(19) United States
(12) Patent Application Publication
(10) Pub. No.: US 2025/0118578 A1
(43) Pub. Date: Apr. 10, 2025

(54) PEDESTAL HEATER WITH SUBSTRATE TEMPERATURE MEASUREMENT SYSTEM

(71) Applicant: Applied Materials, Inc., Santa Clara, CA (US)

(72) Inventors: Ajith Karonnan Ramapurath, Kannur (IN); Jian Li, Fremont, CA (US); Ganesh Balasubramanian, Fremont, CA (US); Juan Carlos Rocha-Alvarez, San Carlos, CA (US)

(73) Assignee: Applied Materials, Inc., Santa Clara, CA (US)

(21) Appl. No.: 18/484,165

(22) Filed: Oct. 10, 2023

(51) Int. Cl. H01L 21/67; H01J 37/32; H01L 21/66; H01L 21/683

(52) U.S. Cl. CPC H01L 21/67248; H01J 37/32449; H01J 37/32724; H01J 37/3299; H01L 21/6833; H01L 22/12; H01J 2237/2007; H01J 2237/24585; H01J 2237/332

(57) ABSTRACT

Exemplary substrate support assemblies may include a support plate that comprises a substrate support surface. The assemblies may include a support stem coupled with the support plate. A channel may be defined through at least a portion of a length of the support stem and extends through the substrate support surface. A temperature sensor assembly may be disposed within the channel. The temperature sensor assembly may include a light pipe disposed within the channel such that a top end of the light pipe extending through at least a portion of the support plate. The temperature sensor assembly may include a sensor that is coupled with a bottom end of the light pipe.

### TECHNICAL FIELD

The present technology relates to components and apparatuses for semiconductor manufacturing. More specifically, the present technology relates to substrate support assemblies and other semiconductor processing equipment.

### BACKGROUND

Integrated circuits are made possible by processes which produce intricately patterned material layers on substrate surfaces. Producing patterned material on a substrate requires controlled methods for forming and removing material. The temperature at which these processes occur may directly impact the final product. Substrate temperatures are often controlled and maintained with the assembly supporting the substrate during processing. Internally located heating devices may generate heat within the support, and the heat may be transferred conductively to the substrate.

As a variety of operational processes may utilize increased temperature as well as substrate-level plasma formation, constituent materials of the substrate support may be exposed to temperatures that affect the electrical operations of the assembly. Thus, there is a need for improved systems and methods that can be used to produce high quality devices and structures. These and other needs are addressed by the present technology.

### SUMMARY

Exemplary substrate support assemblies may include a support plate that may include a substrate support surface. The assemblies may include a support stem coupled with the support plate. A channel may be defined through at least a portion of a length of the support stem and may extend through the substrate support surface. A temperature sensor assembly may be disposed within the channel. The temperature sensor assembly may include a light pipe disposed within the channel such that a top end of the light pipe extends through at least a portion of the support plate. The temperature sensor assembly may include a sensor that is coupled with a bottom end of the light pipe.

In some embodiments, the sensor may include a silicon diode. The sensor may include an optical fiber cable that is coupled with the light pipe. The light pipe may include sapphire. A gas lumen may be defined through at least a portion of the length of the support stem and may extend through the substrate support surface. The gas lumen may be fluidly coupled with the channel. The gas lumen may include a horizontal segment defined within the support plate. The horizontal segment may be fluidly coupled with the channel. The top end of the light pipe may be positioned within 2 mm of a top surface of the substrate support surface. The assemblies may include a cooling hub coupled with a bottom end of the support stem. At least a portion of the sensor may be disposed within the cooling hub.

Some embodiments of the present technology may encompass substrate processing chambers. The chambers may include a chamber body. The chambers may include a faceplate seated atop the chamber body. The chambers may include a substrate support assembly disposed within the chamber body. The chamber body, the faceplate, and the substrate support assembly may define at least a portion of a processing region. The substrate support assembly may include a support plate that may include a substrate support surface. The assembly may include a support stem coupled with the support plate. A channel may be defined through at least a portion of a length of the support stem and may extend through the substrate support surface. The assembly may include a temperature sensor assembly disposed within the channel. The temperature sensor assembly may include a light pipe disposed within the channel such that a top end of the light pipe extends through at least a portion of the support plate. The temperature sensor assembly may include a sensor that is coupled with a bottom end of the light pipe.

In some embodiments, a gas lumen may be defined through at least a portion of the length of the support stem and may extend through the substrate support surface. The chambers may include one or both of a gas source and a vacuum source that is fluidly coupled with a bottom end of the gas lumen. The substrate support assembly may include a cooling hub coupled with a bottom end of the support stem. At least a portion of the sensor may be disposed within the cooling hub. A gas lumen may be defined through at least a portion of the length of the support stem and may extend through the substrate support surface. A bottom end of the gas lumen may extend through a lateral surface of the cooling hub. The substrate support assembly may be operable as an electrostatic chuck. The support plate may include at least one chucking electrode. The support plate may include at least one resistive heating element.

Some embodiments of the present technology may encompass methods of processing a substrate. The methods may include positioning a substrate on a substrate support surface of a substrate support assembly. The methods may include measuring a temperature of the substrate using a sensor assembly. The sensor assembly may include a light pipe that is disposed within a channel that extends through a top surface of the substrate support surface. The sensor assembly may include a sensor that is coupled with the light pipe. The sensor may be disposed within a support stem of the substrate support assembly. The methods may include flowing a precursor into a processing chamber. The methods may include generating a plasma of the precursor within a processing region of the processing chamber. The methods may include depositing a material on the substrate.

In some embodiments, the methods may include flowing a gas into the channel and to a backside of the substrate via a gas lumen defined by the substrate support assembly. The methods may include adjusting at least one of a temperature of the substrate support surface, a flow rate of the precursor, and a plasma-generating current based on the temperature of the substrate.

Such technology may provide numerous benefits over conventional systems and techniques. For example, embodiments of the present technology may provide temperature sensor assemblies that may directly measure a temperature of a substrate. This may provide more accurate substrate temperature measurements. Additionally, the designs may include a purge gas source that may prevent plasma precursors and plasma radicals from reaching the temperature sensor assembly. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma system according to some embodiments of the present technology.

FIG. 3 shows a schematic partial cross-sectional view of an exemplary substrate support assembly according to some embodiments of the present technology.

FIG. 4 shows a schematic partial cross-sectional view of an exemplary substrate support assembly according to some embodiments of the present technology.

FIG. 4A shows a schematic partial isometric view of a support stem of the substrate support assembly of FIG. 4.

FIG. 5 shows a schematic partial cross-sectional view of an exemplary temperature sensor assembly according to some embodiments of the present technology.

FIG. 6 shows exemplary operations in a processing method according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Plasma enhanced deposition processes may energize one or more constituent precursors to facilitate film formation on a substrate. Oftentimes, these processes are performed using pedestals that include heaters which may heat and control the substrate temperature at a desired process temperature. The plasma is generated by exothermic reactions, which may generate significant amounts of heat. While many operations may be performed at sufficiently high temperature to overcome a heat effect from the plasma, when operations occur at mid-range temperatures, such as above or about 100° C. but less than or about 500° C., or less, heat from the plasma may impact the process. This heat, along with heat due to ion bombardment during plasma formation, may exceed the amount of heat that may be dissipated by conventional pedestals to maintain a setpoint temperature. As a result, excess heat may build up that causes a thermal shift that leads to the wafer temperature increasing over time. This temperature increase may lead to film non-uniformity on wafer. To determine whether a substrate is at a desired temperature, conventional processing systems measure the temperature of the pedestal heater plate with an embedded thermocouple. The temperature of the heater plate is used to infer the temperature of the substrate. However, in practice the substrate temperature may be significantly different than the heater plate temperature due to various factors, such as plasma heating, poor heat transfer between the substrate and the heater plate at low pressure, and/or other factors.

The present invention addresses these issues by positioning a light pipe through the heater shaft and heater plate, with a top end of the light pipe being positioned within close proximity (e.g., 0.5 mm) from a bottom surface of the substrate. A bottom end of the light pipe may be coupled with a sensor that may determine a temperature of the substrate. For example, infrared radiation from the substrate may be collected by the light pipe. An optical fiber cable may feed the infrared radiation to the sensor for determining the temperature of the substrate. In some embodiments, a channel in which the light pipe is disposed may be coupled with a purge gas source, which may pump gas into the channel to help prevent any deposition residue from being deposited on the light tube. Embodiments may therefore enable the substrate temperature to be measured directly, rather than inferred from the heater plate temperature.

Although the remaining disclosure will routinely identify specific deposition processes utilizing the disclosed technology, it will be readily understood that the systems and methods are equally applicable to other deposition, etching, and cleaning chambers, as well as processes as may occur in the described chambers. Accordingly, the technology should not be considered to be so limited as for use with these specific deposition processes or chambers alone. The disclosure will discuss one possible system and chamber that may include pedestals according to embodiments of the present technology before additional variations and adjustments to this system according to embodiments of the present technology are described.

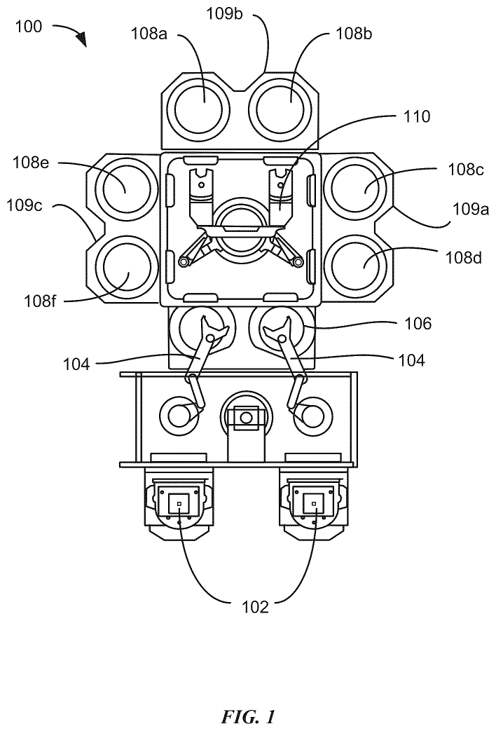

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

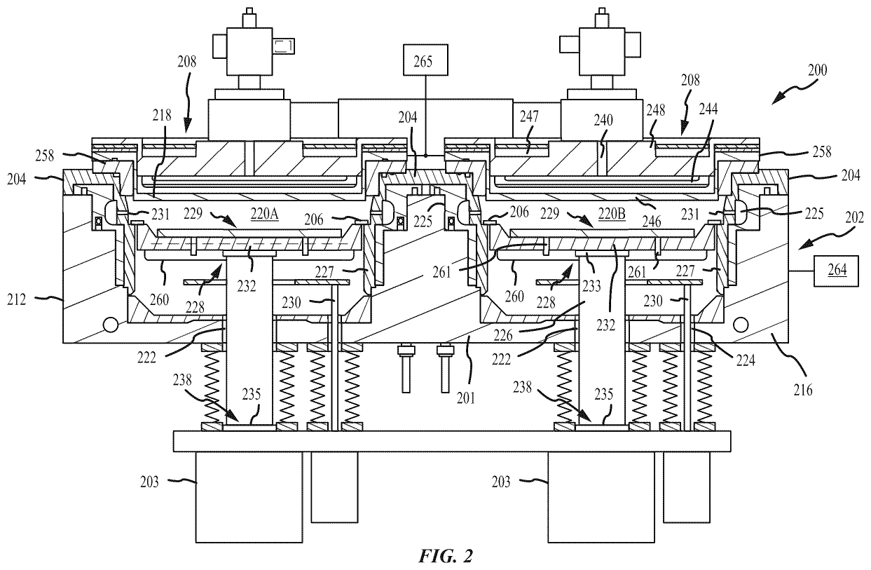

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include substrate support assemblies according to embodiments of the present technology. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a dual-channel showerhead 218 into the processing region 220B. The dual-channel showerhead 218 may include an annular base plate 248 having a blocker plate 244 disposed intermediate to a faceplate 246. A radio frequency (“RF”) source 265 may be coupled with the dual-channel showerhead 218, which may power the dual-channel showerhead 218 to facilitate generating a plasma region between the faceplate 246 of the dual-channel showerhead 218 and the pedestal 228. In some embodiments, the RF source may be coupled with other portions of the chamber body 202, such as the pedestal 228, to facilitate plasma generation. A dielectric isolator 258 may be disposed between the lid 204 and the dual-channel showerhead 218 to prevent conducting RF power to the lid 204. A shadow ring 206 may be disposed on the periphery of the pedestal 228 that engages the pedestal 228.

An optional cooling channel 247 may be formed in the annular base plate 248 of the gas distribution system 208 to cool the annular base plate 248 during operation. A heat transfer fluid, such as water, ethylene glycol, a gas, or the like, may be circulated through the cooling channel 247 such that the base plate 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

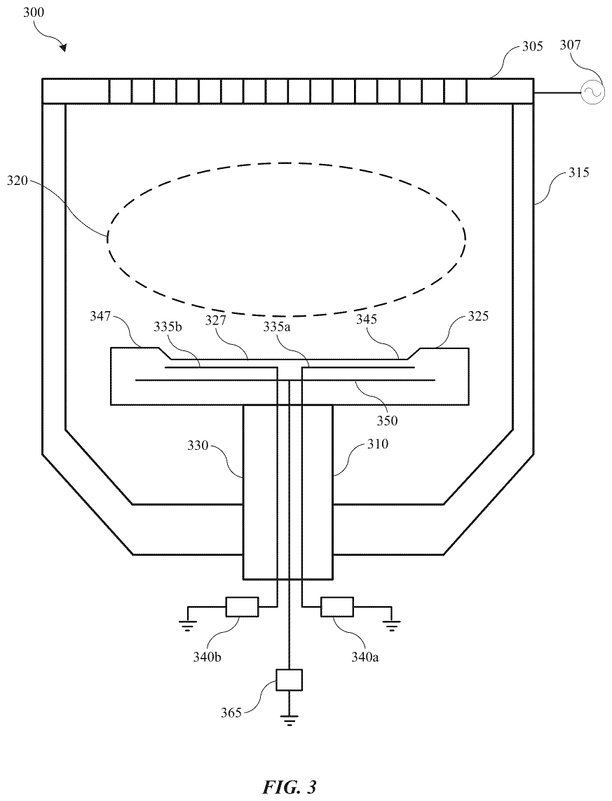

FIG. 3 shows a schematic partial cross-sectional view of an exemplary semiconductor processing chamber 300 according to some embodiments of the present technology. FIG. 3 may include one or more components discussed above with regard to FIG. 2, and may illustrate further details relating to that chamber. The chamber 300 may be used to perform semiconductor processing operations including deposition of stacks of dielectric materials as previously described. Chamber 300 may show a partial view of a processing region of a semiconductor processing system, and may not include all of the components, such as additional lid stack components previously described, which are understood to be incorporated in some embodiments of chamber 300.

As noted, FIG. 3 may illustrate a portion of a processing chamber 300. The chamber 300 may include a showerhead 305, as well as a substrate support assembly 310. Along with chamber sidewalls 315, the showerhead 305 and the substrate support 310 may define a substrate processing region 320 in which plasma may be generated. The substrate support assembly may include an electrostatic chuck body 325, which may include one or more components embedded or disposed within the body. The components incorporated within the top puck may not be exposed to processing materials in some embodiments, and may be fully retained within the chuck body 325. Electrostatic chuck body 325 may define a substrate support surface 327, and may be characterized by a thickness and length or diameter depending on the specific geometry of the chuck body. In some embodiments the chuck body may be elliptical, and may be characterized by one or more radial dimensions from a central axis through the chuck body. It is to be understood that the top puck may be any geometry, and when radial dimensions are discussed, they may define any length from a central position of the chuck body.

Electrostatic chuck body 325 may be coupled with a stem 330, which may support the chuck body and may include channels for delivering and receiving electrical and/or fluid lines that may couple with internal components of the chuck body 325. Chuck body 325 may include associated channels or components to operate as an electrostatic chuck, although in some embodiments the assembly may operate as or include components for a vacuum chuck, or any other type of chucking system. Stem 330 may be coupled with the chuck body on a second surface of the chuck body opposite the substrate support surface. In some embodiments, the electrostatic chuck body 325 may be formed from a conductive material (such as a metal like aluminum or any other material that may be thermally and or electrically conductive) and may be coupled with a source of electric power (such as DC power, pulsed DC power, RF bias power, a pulsed RF source or bias power, or a combination of these or other power sources) through a filter, which may be an impedance matching circuit to enable the electrostatic chuck body 325 to operate as an electrode. In other embodiments, a top portion of the electrostatic chuck body 325 may be formed from a dielectric material. In such embodiments, the electrostatic chuck body 325 may include separate electrodes. For example, the electrostatic chuck body 325 may include a first bipolar electrode 335a, which may be embedded within the chuck body proximate the substrate support surface. Electrode 335a may be electrically coupled with a DC power source 340a. Power source 340a may be configured to provide energy or voltage to the electrically conductive chuck electrode 335a. This may be operated to form a plasma of a precursor within the processing region 320 of the semiconductor processing chamber 300, although other plasma operations may similarly be sustained. For example, electrode 335a may also be a chucking mesh that operates as electrical ground for a capacitive plasma system including an RF source 307 electrically coupled with showerhead 305. For example, electrode 335a may operate as a ground path for RF power from the RF source 307, while also operating as an electric bias to the substrate to provide electrostatic clamping of the substrate to the substrate support surface. Power source 340a may include a filter, a power supply, and a number of other electrical components configured to provide a chucking voltage.

The electrostatic chuck body may also include a second bipolar electrode 335b, which may also be embedded within the chuck body proximate the substrate support surface. Electrode 335b may be electrically coupled with a DC power source 340b. Power source 340b may be configured to provide energy or voltage to the electrically conductive chuck electrode 335b. Additionally electrical components and details about bipolar chucks according to some embodiments will be described further below, and any of the designs may be implemented with processing chamber 300. For example, additional plasma related power supplies or components may be incorporated.

In operation, a substrate may be in at least partial contact with the substrate support surface of the electrostatic chuck body, which may produce a contact gap, and which may essentially produce a capacitive effect between a surface of the pedestal and the substrate. Voltage may be applied to the contact gap, which may generate an electrostatic force for chucking. The power supplies 340a and 340b may provide electric charge that migrates from the electrode to the substrate support surface where it may accumulate, and which may produce a charge layer having Coulomb attraction with opposite charges at the substrate, and which may electrostatically hold the substrate against the substrate support surface of the chuck body. This charge migration may occur by current flowing through a dielectric material of the chuck body based on a finite resistance within the dielectric for Johnsen-Rahbek type chucking, which may be used in some embodiments of the present technology.

Chuck body 325 may also define a recessed region 345 within the substrate support surface, which may provide a recessed pocket in which a substrate may be disposed. Recessed region 345 may be formed at an interior region of the top puck and may be configured to receive a substrate for processing. Recessed region 345 may encompass a central region of the electrostatic chuck body as illustrated, and may be sized to accommodate any variety of substrate sizes. A substrate may be seated within the recessed region, and contained by an exterior region 347, which may encompass the substrate. In some embodiments the height of exterior region 347 may be such that a substrate is level with or recessed below a surface height of the substrate support surface at exterior region 347. A recessed surface may control edge effects during processing, which may improve uniformity of deposition across the substrate in some embodiments. In some embodiments, an edge ring may be disposed about a periphery of the top puck, and may at least partially define the recess within which a substrate may be seated. In some embodiments, the surface of the chuck body may be substantially planar, and the edge ring may fully define the recess within which the substrate may be seated.

In some embodiments the electrostatic chuck body 325 and/or the stem 330 may be insulative or dielectric materials. For example, oxides, nitrides, carbides, and other materials may be used to form the components. Exemplary materials may include ceramics, including aluminum oxide, aluminum nitride, silicon carbide, tungsten carbide, and any other metal or transition metal oxide, nitride, carbide, boride, or titanate, as well as combinations of these materials and other insulative or dielectric materials. Different grades of ceramic materials may be used to provide composites configured to operate at particular temperature ranges, and thus different ceramic grades of similar materials may be used for the top puck and stem in some embodiments. Dopants may be incorporated in some embodiments to adjust electrical properties as well. Exemplary dopant materials may include yttrium, magnesium, silicon, iron, calcium, chromium, sodium, nickel, copper, zinc, or any number of other elements known to be incorporated within a ceramic or dielectric material.

Electrostatic chuck body 325 may also include an embedded heater 350 contained within the chuck body. Heater 350 may include a resistive heater or a fluid heater in embodiments. In some embodiments the electrode 335 may be operated as the heater, but by decoupling these operations, more individual control may be afforded, and extended heater coverage may be provided while limiting the region for plasma formation. Heater 350 may include a polymer heater bonded or coupled with the chuck body material, although a conductive element may be embedded within the electrostatic chuck body and configured to receive current, such as AC current, to heat the top puck. The current may be delivered through the stem 330 through a similar channel as the DC power discussed above. Heater 350 may be coupled with a power supply 365, which may provide current to a resistive heating element to facilitate heating of the associated chuck body and/or substrate. Heater 350 may include multiple heaters in embodiments, and each heater may be associated with a zone of the chuck body, and thus exemplary chuck bodies may include a similar number or greater number of zones than heaters. If present, the chucking mesh electrodes 335 may be positioned between the heater 350 and the substrate support surface 327 in some embodiments, and a distance may be maintained between the electrode within the chuck body and the substrate support surface in some embodiments as will be described further below.

The heater 350 may be capable of adjusting temperatures across the electrostatic chuck body 325, as well as a substrate residing on the substrate support surface 327. The heater may have a range of operating temperatures to heat the chuck body and/or a substrate above or about 100° C., and the heater may be configured to heat above or about 125° C., above or about 150° C., above or about 175° C., above or about 200° C., above or about 250° C., above or about 300° C., above or about 350° C., above or about 400° C., above or about 450° C., above or about 500° C., above or about 550° C., above or about 600° C., above or about 650° C., above or about 700° C., above or about 750° C., above or about 800° C., above or about 850° C., above or about 900° C., above or about 950° C., above or about 1000° C., or higher. The heater may also be configured to operate in any range encompassed between any two of these stated numbers, or smaller ranges encompassed within any of these ranges, as well as less than any of the stated temperatures. In some embodiments, the chamber 300 may include a purge gas source, such as a purge gas source fluidly coupled with a bottom of the chamber body 315. The purge gas source may supply a purge gas to the chamber 300 to remove any film that has been deposited on various components of the chamber 300, such as the support assembly 310.

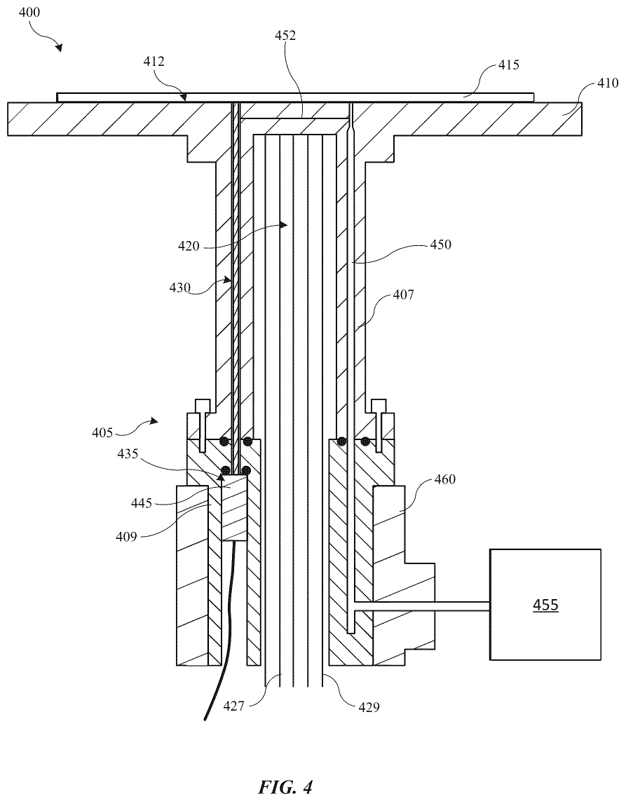

FIG. 4 illustrates a schematic partial cross-sectional view of a substrate support assembly 400 according to some embodiments of the present technology. As explained above, the present technology may be used in some embodiments to perform film depositions and cures within a single chamber. Substrate support assembly 400 may be similar to substrate support assembly 310, and may include any feature, component, or characteristic of the support described above, including any associated components or power supplies. Substrate support assembly 400 may include a support stem 405, which may be a conductive or dielectric material in some embodiments. A support plate 410 may be seated atop and/or coupled with support stem 405. Support plate 410 may be formed from one or more plates, which may be formed from any combination of conductive and/or dielectric materials. In the illustrated embodiment, support stem 405 and support plate 410 are both formed from dielectric materials. In some embodiments, support stem 405 and support plate 410 may be integrally formed, while in other embodiments support stem 405 and support plate 410 may be separately formed and later joined.

In some embodiments, support stem 405 may be formed as a single component. In other embodiments, support stem 405 may be formed from multiple segments. For example, as illustrated support stem 405 includes and upper segment 407 and a lower segment 409 that are coupled together. Here, upper segment 407 is formed from a dielectric material, such as (but not limited to) aluminum nitride, while lower segment 409 may be formed from a conductive material, such as aluminum. In some embodiments, each segment of support stem 405 may include a flange, with the flanges being positioned against one another to secure the segments together. For example, bolts, clamps, and/or other fasteners may be engaged with the flanges to secure the segments of support stem 405 together. The use of multiple support stem segments may enable different materials to be used to form support stem 405. This may enable upper segment 407 and support plate 410 may be heated to facilitate processing operations, while the conductive lower segment 409 of support stem 405 to be actively cooled to prevent residue from depositing on lower portions of support stem 405.

Support plate 410 may define a substrate support surface 412, which may be sized and shaped to be substantially a same size as a substrate 415 to be processed. The substrate support surface 412 may be coplanar with an outer portion of support plate 410 or may be recessed below or raised above the outer portion of support plate 410 in some embodiments. Substrate support surface 412 may be a substantially planar surface or may include a number of mesas or other protrusions upon which substrate 415 may be seated. Support plate 410 may include a number of additional components. For example, support plate 410 may include one or more components embedded or disposed within support plate 410. The components incorporated within support plate 410 may not be exposed to processing materials in some embodiments and may be fully retained within support plate 410. For example, one or more heating elements (such as resistive heating elements) and/or chucking electrodes may be disposed within support plate 410. In some embodiments, support plate 410 may define one or more cooling channels (not shown) that enable a cooling fluid, such as water or galden, to be circulated through each cooling channel to cool a lower portion of support plate 410 to help dissipate excess heat generated during the plasma formation process, which may reduce or eliminate thermal shift and result in more uniform film deposition on the substrate.

In some embodiments, the heating elements may be formed from a conductive wire, such as a wire formed from nickel chromium. An insulating shell may be provided about the heating element to prevent shorting. The heating element may be formed from one or more components. As just one example, conductive wire may be provided in a radially expanding spiral or other circuitous shape within support plate 410 to provide relatively uniform heating across substrate support surface 412. Each heating element may be coupled with a power source, such as an AC power source that delivers AC current to the heating element, to heat support plate 410. The current may be delivered to the heating element through one or more rods 427 or wires that are disposed within channel 420 formed within stem 405 and support plate 410. The heating element may have a range of operating temperatures to heat support plate 410 and/or substrate 415 above or about 100° C., above or about 125° C., above or about 150° C., above or about 175° C., above or about 200° C., above or about 250° C., above or about 300° C., above or about 350° C., above or about 400° C., above or about 450° C., above or about 500° C., above or about 550° C., above or about 600° C., or higher. The heating elements may also be configured to operate in any range encompassed between any two of these stated numbers, or smaller ranges encompassed within any of these ranges.

The chucking electrodes may be monopolar or bipolar and may be coupled with one or more power sources via one or more wires or rods 429 that are disposed within channel 420. Each rod 429 may be coupled with an RF match of a low-frequency power supply to provide a chucking current. Each rod 429 may have a rod insulator extending about the respective rod 429, and that may extend with the RF rod through support stem 405 and support plate 410. In some embodiments, rather than being coupled with chucking electrodes, rod 429 may be coupled with support plate 410, which may operate as a plasma electrode and/or as a chucking electrode. In some embodiments, rather than, or in addition to, operating as an electrostatic chuck, substrate support assembly 400 may operate as a vacuum chuck. For example, when the chamber is at a low pressure, substrate support assembly 400 may operate as an electrostatic chuck, and when the chamber is operated at a higher pressure, substrate support assembly 400 may operate as a vacuum chuck and/or electrostatic chuck.

Support stem 405 and support plate 410 may define a channel 430 that extends through a full thickness of support plate 410 and through at least a portion of a length of support stem 405. For example, a top end of channel 430 may extend through a top surface of support plate 410, such as extending through substrate support surface 412. Channel 430 may have a constant or variable diameter along a length of channel 430. For example, as illustrated, channel 430 may have a narrower diameter along an upper portion of channel 430 and a larger diameter along a lower portion of channel 430. A transition between the different diameters may be tapered and/or stepped as illustrated here. In some embodiments, a narrower diameter (e.g., in upper portion) of channel 430 may be between or about 1.5 mm and 5 mm or between or about 2 mm and 3 mm. In some embodiments, the larger diameter portion of channel 430 may be formed within the conductive lower segment 409 of support stem 405.

Disposed within channel 430 may be a temperature sensor assembly 435. Temperature sensor assembly 435 may include a light pipe 440 that may be disposed within channel 430, such as the upper portion of channel 430. For example, light pipe 440 may be disposed within channel 430 such that a bottom end of light pipe 440 is disposed within support stem 405 and such that top end of light pipe 440 extends through at least a portion of support plate 410 and is in close proximity to substrate support surface 412 and substrate 415. For example, the top end of light pipe 440 may be disposed within 2 mm of substrate support surface 412 and substrate 415, within 1.75 mm of substrate support surface 412 and substrate 415, within 1.5 mm of substrate support surface 412 and substrate 415, within 1.25 mm of substrate support surface 412 and substrate 415, within 1 mm of substrate support surface 412 and substrate 415, within 0.75 mm of substrate support surface 412 and substrate 415, within 0.5 mm of substrate support surface 412 and substrate 415, within 0.25 mm of substrate support surface 412 and substrate 415, or less. Such close proximity may enable light pipe 440 to effectively collect infrared radiation from substrate 415 that may be used to determine a temperature of substrate 415. In some embodiments, light pipe 440 may be formed from sapphire, although other materials that are capable of conducting infrared radiation may be used in various embodiments.

In some embodiments, an outer diameter of light pipe 440 may be between or about 1 mm and 4 mm, between or about 1.25 mm and 3.5 mm, between or about 1.5 mm and 3 mm, or between or about 1.75 mm and 2.5 mm. In some embodiments, a diameter of channel 430 may be greater than a diameter of light pipe 440 by between or about 0.1 mm and 2 mm, between or about 0.25 mm and 1.5 mm, or between or about 0.5 mm and 1 mm. A length of light pipe 440 may be between or about 100 mm and 400 mm, between or about 150 mm and 300 mm, or between or about 175 mm and 250 mm, although other lengths are possible in various embodiments.

Temperature sensor assembly 435 may include a sensor 445 that is coupled with a bottom end of light pipe 440. Sensor 445 may be directly or indirectly coupled with light pipe 440. For example, an optical fiber cable (not shown) may be disposed between sensor 445 and light pipe 440. In some embodiments, sensor 445 may have a larger cross-section than light pipe 440. In such embodiments, light pipe 440 may be disposed in a narrower portion of channel 430 (e.g., the upper portion) and sensor 445 may be disposed in a wider portion of channel 430 (e.g., the lower portion). For example, all or an upper portion of light pipe 440 may be disposed within upper segment 407 of support stem 405 while all or a part of sensor 445 (and possibly a lower portion of light pipe 440) may be disposed within lower segment 409 of support stem 405. Sensor 445 may include a silicon diode optical detector in some embodiments, although other optical detectors may be utilized in various embodiments.

Temperature sensor assembly 435 may be utilized to measure a temperature of substrate 415. For example, infrared radiation from substrate 415 may be collected by light pipe 440, which may feed the infrared radiation to a optical fiber cable. Sensor 445 may receive the infrared radiation from the optical fiber cable and may measure the infrared radiation to determine the temperature of substrate 415. The temperature of substrate 415 may be used to tune one or more process variables such as, but not limited to, a plasma-generating current, a flow rate of one or more plasma precursors, a temperature of support plate 410, and/or other processing parameters to optimize a given process recipe.

In some embodiments, support stem 405 and support plate 410 may define a gas lumen 450 that extends through a full thickness of support plate 410 and through at least a portion of a length of support stem 405. For example, a top end of gas lumen 450 may extend through a top surface of support plate 410, such as extending through substrate support surface 412. Gas lumen 450 may extend downward through support stem 405 and may be fluidly coupled with a fluid unit 455, such as at a bottom end of gas lumen 450. In some embodiments, fluid unit 455 may be a gas source that may supply a backside gas, such as a thermal transfer gas and/or a purge gas through gas lumen 450 to a backside of substrate 415. For example, in some embodiments the backside gas may be helium or another inert gas. In some embodiments fluid unit 455 may be a vacuum source that may be used to chuck substrate 415 against substrate support surface 412.

In some embodiments, in addition to providing gas to the backside of substrate 415, gas lumen 450 may deliver gas to channel 430. For example, helium or another inert gas may be pumped into channel 430 at a position below substrate-receiving surface 412 to prevent process gases and/or plasma radicals from depositing residue on and/or damaging light pipe 440. In such embodiments, gas lumen 450 may be fluidly coupled with a medial portion of channel 430, such as via one or more laterally extending segments of gas lumen 450. For example, gas lumen 450 may include one or more horizontal segments 452 that are embedded and/or otherwise defined within stem 405 and/or support plate 410 and that extend to and are fluidly coupled with channel 430. As illustrated in FIG. 4A, horizontal segment 452 are provided in the form of an annular channel that extends about an upper surface of support stem 405. When support plate 410 is positioned atop support shaft 405, the annular channel forms a fluid path that may direct some or all gas from gas lumen 450 into channel 430 to help purge channel 430.

Substrate support assembly 400 may include a cooling hub 460 that may be coupled with a bottom end of support stem 405. For example, cooling hub 460 may be formed from a thermally conductive material, such as aluminum and may be coupled with one or more sources of cooling fluid. The cooling fluid may be circulated through one or more channels (not shown) formed within cooling hub 460 to help cool lower segment 409 of support stem 405 and cooling hub 460. In some embodiments, at least a portion of sensor 445 may be disposed within cooling hub 460. For example, sensor 445 may be disposed in lower segment 409 of support stem 405, with some or all of lower segment 409 and sensor 445 being surrounded by a portion of cooling hub 460. Such positioning may enable cooling hub 460 to help maintain sensor 445 within an operating temperature range. In some embodiments, a bottom end of gas lumen 450 may extend through a lateral surface of cooling hub 460, which may enable fluid unit 455 to be coupled with the lateral surface of cooling hub 460 to fluidly couple with gas lumen 450.

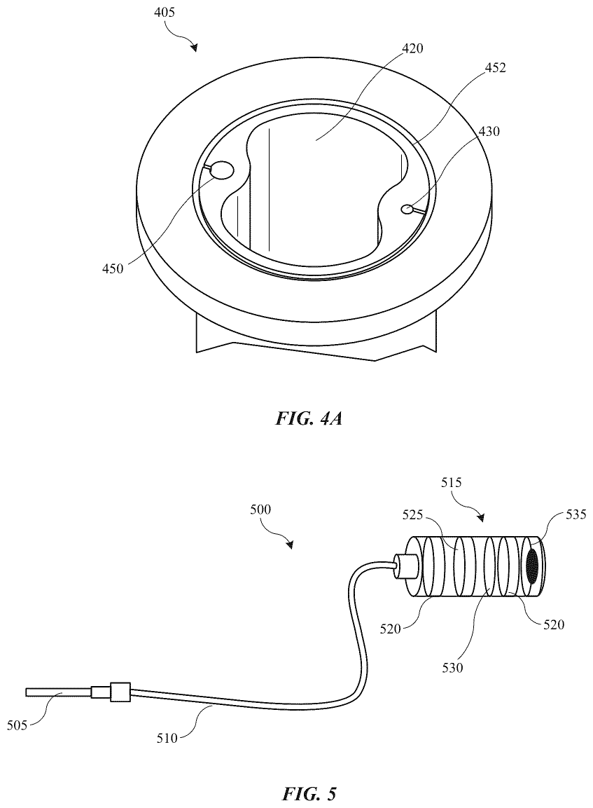

FIG. 5 illustrates a schematic partial cross-sectional view of a temperature sensor assembly 500 according to some embodiments of the present technology. Temperature sensor assembly 500 may be used as temperature sensor assembly 435, and may include any feature, component, or characteristic of temperature sensor assembly 435. Temperature sensor assembly 500 may include a light pipe 505. A top end of light pipe 505 may be positioned in proximity to a substrate within a processing chamber. Light pipe 505 may be formed of sapphire in some embodiments, however other materials may be utilized. An optical fiber cable 510 may be coupled with a bottom end of light pipe 505. In some embodiments an end of optical fiber cable 510 may be inserted within a portion of light pipe 505. A bottom end of optical fiber cable 510 may be coupled with a sensor 515. Sensor 515 may include one or more lenses 520, a restricting aperture 525, a wavelength specific optical filter 530, and/or other components that filter and/or focus infrared radiation from light pipe 505 and optical fiber cable 510 onto an optical detector 535. Optical detector 535 may include a silicon diode in some embodiments, although optical detector 535 may take other forms.

In operation, temperature sensor assembly 500 may be utilized to perform in situ measurements of a temperature of a substrate positioned within a processing chamber. For example, light pipe 505 may be disposed within a channel that extends through a substrate support surface of a substrate support assembly such that light pipe 505 is disposed in close proximity to a bottom surface of the substrate. Infrared radiation from the substrate may be collected by light pipe 505, which may feed the infrared radiation to optical fiber cable 510. The infrared radiation from optical fiber cable 510 may be conducted to lenses 520, restricting aperture 525, wavelength specific optical filter 530, and/or other components that may filter and focus the infrared radiation to optical detector 535. Optical detector 535 may measure the infrared radiation to determine the temperature of the substrate. The temperature of the substrate may be used to tune one or more process variables such as, but not limited to, a plasma-generating current, a flow rate of one or more plasma precursors, a temperature of the support plate, and/or other processing parameters to optimize a given process recipe.

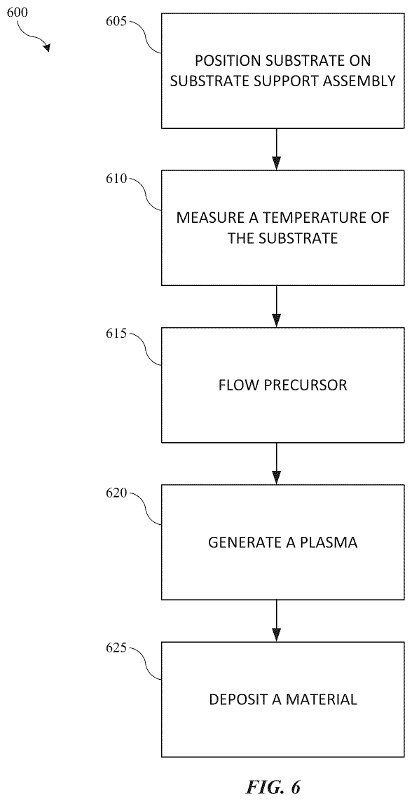

FIG. 6 shows operations of an exemplary method 600 of semiconductor processing according to some embodiments of the present technology. The method may be performed in a variety of processing chambers, including processing system 200 or chamber 300 described above, which may include substrate support assemblies according to embodiments of the present technology, such as substrate support assembly 310 and 400 described herein. Method 600 may include a number of optional operations, which may or may not be specifically associated with some embodiments of methods according to the present technology.

Method 600 may include a processing method that may include operations for forming a hardmask film or other deposition operations. The method may include optional operations prior to initiation of method 600, or the method may include additional operations. For example, method 600 may include operations performed in different orders than illustrated. In some embodiments, method 600 may include positioning a substrate on a substrate support surface of a substrate support assembly at operation 605. At operation 610 a temperature of the substrate may be measured using a temperature sensor assembly (which may be similar to temperature sensor assemblies 445 and 500. For example, the temperature sensor assembly may include a light pipe that is disposed within a channel that extends through a top surface of the substrate support surface. The temperature sensor assembly may also include a sensor that is coupled with the light pipe. The sensor may be disposed within a support stem of the substrate support assembly. Measuring the temperature of the substrate may include collecting infrared radiation from the substrate using the light pipe. The infrared radiation may be conducted to the sensor, which may measure the infrared radiation to determine the temperature of the substrate.

In some embodiments, method 600 may include heating a top surface of the substrate support assembly. For example, an AC current may be supplied to a heating element and/or a dielectric support plate to heat a top portion of the support plate. One or more precursors may be flowed into a processing chamber at operation 615. For example, the precursor may be flowed into a chamber, such as chamber 300. At operation 620, a plasma may be generated of the precursors within the processing region, such as by providing RF power to the faceplate and/or substrate support assembly to generate a plasma. Material formed in the plasma may be deposited on the substrate at operation 625.

In some embodiments, the measured temperature of the substrate may be used to adjust one or more processing parameters. For example, based on the measured temperature of the substrate, a temperature of the substrate support surface, a flow rate of the precursor, a plasma-generating current based on the temperature of the substrate, and/or other process parameter may be varied to achieve a desired deposition rate/profile based on the current substrate temperature. In some embodiments, method 600 may include flowing a gas into the channel and to a backside of the substrate via a gas lumen defined by the substrate support assembly. The flow of gas into the channel may help prevent any precursor and/or plasma radicals from depositing residue on and/or damaging the light pipe or other component of temperature sensor assembly.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Unless defined otherwise, all technical and scientific terms used herein have the same meaning as commonly or conventionally understood. As used herein, the articles “a” and “an” refer to one or to more than one (i.e., to at least one) of the grammatical object of the article. By way of example, “an element” means one element or more than one element. “About” and/or “approximately” as used herein when referring to a measurable value such as an amount, a temporal duration, and the like, encompasses variations of +20% or +10%, +5%, or +0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of +20% or +10%, +5%, or +0.1% from the specified value, as such variations are appropriate to in the context of the systems, devices, circuits, methods, and other implementations described herein.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A substrate support assembly, comprising:
a support plate that comprises a substrate support surface;
a support stem coupled with the support plate, wherein a channel is defined through at least a portion of a length of the support stem and extends through the substrate support surface; and
a temperature sensor assembly disposed within the channel, the temperature sensor assembly comprising:
a light pipe disposed within the channel such that a top end of the light pipe extends through at least a portion of the support plate; and
a sensor that is coupled with a bottom end of the light pipe.

2. The substrate support assembly of claim 1, wherein:
the sensor comprises a silicon diode.

3. The substrate support assembly of claim 1, wherein:
the sensor comprises an optical fiber cable that is coupled with the light pipe.

4. The substrate support assembly of claim 1, wherein:
the light pipe comprises sapphire.

5. The substrate support assembly of claim 1, wherein:
a gas lumen is defined through at least a portion of the length of the support stem and extends through the substrate support surface.

6. The substrate support assembly of claim 5, wherein:
the gas lumen is fluidly coupled with the channel.

7. The substrate support assembly of claim 6, wherein:
the gas lumen comprises a horizontal segment defined within the support plate; and
the horizontal segment is fluidly coupled with the channel.

8. The substrate support assembly of claim 1, wherein:
the top end of the light pipe is positioned within 2 mm of a top surface of the substrate support surface.

9. The substrate support assembly of claim 1, further comprising:
a cooling hub coupled with a bottom end of the support stem, wherein at least a portion of the sensor is disposed within the cooling hub.

10. A substrate processing chamber, comprising:
a chamber body;
a faceplate seated atop the chamber body; and
a substrate support assembly disposed within the chamber body, wherein the chamber body, the faceplate, and the substrate support assembly defining at least a portion of a processing region, and wherein the substrate support assembly comprises:
a support plate that comprises a substrate support surface;
a support stem coupled with the support plate, wherein a channel is defined through at least a portion of a length of the support stem and extends through the substrate support surface; and
a temperature sensor assembly disposed within the channel, the temperature sensor assembly comprising:
a light pipe disposed within the channel such that a top end of the light pipe extends through at least a portion of the support plate; and
a sensor that is coupled with a bottom end of the light pipe.

11. The substrate processing chamber of claim 10, wherein:
a gas lumen is defined through at least a portion of the length of the support stem and extends through the substrate support surface.

12. The substrate processing chamber of claim 11, further comprising:
one or both of a gas source and a vacuum source that is fluidly coupled with a bottom end of the gas lumen.

13. The substrate processing chamber of claim 10, wherein:
the substrate support assembly comprises a cooling hub coupled with a bottom end of the support stem, wherein at least a portion of the sensor is disposed within the cooling hub.

14. The substrate processing chamber of claim 13, wherein:
a gas lumen is defined through at least a portion of the length of the support stem and extends through the substrate support surface; and
a bottom end of the gas lumen extends through a lateral surface of the cooling hub.

15. The substrate processing chamber of claim 10, wherein:
the substrate support assembly is operable as an electrostatic chuck.

16. The substrate processing chamber of claim 15, wherein:
the support plate comprises at least one chucking electrode.

17. The substrate processing chamber of claim 10, wherein:
the support plate comprises at least one resistive heating element.

18. A method of processing a substrate, comprising:
positioning a substrate on a substrate support surface of a substrate support assembly;
measuring a temperature of the substrate using a sensor assembly, the sensor assembly comprising:
a light pipe that is disposed within a channel that extends through a top surface of the substrate support surface; and
a sensor that is coupled with the light pipe, the sensor being disposed within a support stem of the substrate support assembly;
flowing a precursor into a processing chamber;
generating a plasma of the precursor within a processing region of the processing chamber; and
depositing a material on the substrate.

19. The method of processing a substrate of claim 18, further comprising:
flowing a gas into the channel and to a backside of the substrate via a gas lumen defined by the substrate support assembly.

20. The method of processing a substrate of claim 18, further comprising:
adjusting at least one of a temperature of the substrate support surface, a flow rate of the precursor, and a plasma-generating current based on the temperature of the substrate.
